(19) United States
(12) Patent Application Publication
(10) Pub. No.: US 2026/0063747 A1
(43) Pub. Date: Mar. 5, 2026

(54) FAULT DETECTION SYSTEMS METHODS, AND DEVICES FOR A CURRENT MEASUREMENT CIRCUIT IN BATTERY STACKS

(71) Applicant: Nuvation Research Corporation, Sunnyvale, CA (US)

(72) Inventors: Steven Miller, Waterloo (CA); Ryan Chung, Richmond Hill (CA); Manoj Mathew, Kitchener (CA); Alex Ramji, Waterloo (CA); Nathanael Wennyk, Waterloo (CA)

(73) Assignee: Nuvation Research Corporation, Sunnyvale, CA (US)

(21) Appl. No.: 19/039,683

(22) Filed: Jan. 28, 2025

Related U.S. Application Data
(60) Provisional application No. 63/688,736, filed on Aug. 29, 2024.

(51) Int. Cl. G01R 35/00; G01K 3/04; G01K 3/08; G01R 31/382; H02H 7/18

(52) U.S. Cl. CPC G01R 35/00; G01K 3/04; G01K 3/08; G01R 31/382; H02H 7/18

(57) ABSTRACT

Fault detection devices and methods, for detecting a current measurement circuit failure for an energy storage system in an energy storage system, are disclosed. An example device comprising: a temperature measurement module configured to determine a resistive element temperature and an ambient temperature, a current measurement module configured to determine a measured current of a current sensor connected to the energy storage system; a current circuit fault detection module configured to determine a failure condition is met based on the resistive element temperature, the ambient temperature and the measured current and generate a fault signal based on the failure condition; and a switch positioned between the load and the battery, the switch controlled based on the fault signal received from the current circuit fault detection module.

### CROSS-REFERENCE TO RELATED APPLICATION

This application claims priority to U.S. Provisional Patent Application No. 63/688,736, filed Aug. 29, 2024 and entitled “FAULT DETECTION SYSTEMS METHODS, AND DEVICES FOR A CURRENT MEASUREMENT CIRCUIT IN BATTERY STACKS,” the disclosures of which are hereby incorporated by reference herein.

### FIELD OF INVENTION

The present disclosure relates generally to safety and protection systems for battery stacks, in particular to detecting and managing failures in current measurement circuits to bring the battery stack to a safe state.

### BACKGROUND

One of the key responsibilities of a battery management system (BMS) is to ensure safe operation of the energy storage systems (ESS). Several different failure conditions can occur during operation. One such failure is a short across the current measurement sensor, resulting in erroneous measurements. Numerous safety protections within the BMS rely on an accurate current measurement. Therefore, the BMS must be able to determine if the current measurements it is reading are reliable.

Current methods for determining incorrect current measurements within a battery system include measuring current and/or voltage and utilizing modeling, such as battery modeling or ESS modeling to determine if the measurements can be trusted. The disadvantage with this approach is that it relies on a battery model which can be difficult to configure and often has a high computational cost when implemented on a resource limited microcontroller. In addition, lithium iron phosphate (LFP) batteries have a very flat open-circuit voltage curve, which makes model predictions very difficult. A second method for determining incorrect current measurements is to use two current sensors. However, a second sensor can add to the total cost of the ESS.

Therefore, systems, methods and devices that allow for detection of failures in the current measurement circuit without requiring a battery or ESS model are desirable.

### SUMMARY OF THE INVENTION

A method for detecting a current measurement circuit failure in an energy storage system is disclosed comprising a load and a battery, the method comprising: determining a resistive element temperature of a resistive element, wherein the determining the resistive element temperature is based on a measurement by a temperature sensor, wherein the resistive element is electrically connected between the load and the battery; determining, by a computing unit, a measured current across a current sensor connected to the energy storage system; determining, by the computing unit, a current measurement circuit failure condition based on the resistive element temperature and the measured current; generating, by the computing unit, a fault signal, the fault signal based on the determining the current measurement circuit failure condition; and controlling, by the computing unit, a switch based on the fault signal, the switch positioned between the battery and the load.

A fault detection device for an energy storage system is disclosed comprising a battery and a load, the device comprising: a temperature measurement module configured to determine a resistive element temperature and an ambient temperature, wherein the resistive element temperature is based on a resistive element electrically connected between the load and the battery; a current measurement module configured to determine a measured current of a current sensor connected to the energy storage system; a current circuit fault detection module configured to determine a failure condition is met based on the resistive element temperature, the ambient temperature and the measured current and generate a fault signal based on the failure condition; and a switch positioned between the load and the battery, the switch controlled based on the fault signal received from the current circuit fault detection module.

A fault detection system for an energy storage system is disclosed comprising a battery and a load, the system comprising: a current sensor in connection between the battery and the load, the current sensor having a measured current; a first temperature sensor for measuring a resistive element temperature, the resistive element temperature based on the temperature of a resistive element, wherein the resistive element is electrically connected between the battery and the load; a second temperature sensor for measuring an ambient temperature, the ambient temperature based on the temperature of the energy storage system; a computing unit in communication with the current sensor, the first temperature sensor and the second temperature sensor, the computing unit comprising a tangible, non-transitory memory configured to communicate with the processor, the tangible, non-transitory memory having instructions stored thereon that, in response to execution by the processor, cause the processor to perform operations comprising: determining a failure condition is met based on the resistive element temperature, the ambient temperature and the measured current; generating a fault signal, the fault signal based on the failure condition; and controlling a switch based on the fault signal, the switch in communication with the switch and the battery.

### BRIEF DESCRIPTION OF THE DRAWING FIGURES

Additional aspects of the present disclosure will become evident upon reviewing the non-limiting embodiments described in the specification and the claims taken in conjunction with the accompanying figures, wherein like numerals designate like elements, and:

FIG. 1A is a diagram illustrating an example energy storage cell;

FIG. 1B is a diagram illustrating an example battery stack;

FIG. 2 is a block diagram illustrating energy storage system comprising a fault detection system, in accordance with various embodiments;

FIG. 3 is a block diagram illustrating various modules for a fault detection system for detecting failures in current measurement circuits; and

FIG. 4 illustrates a method for detecting a current measurement circuit failure for a battery, in accordance with various embodiments.

### DETAILED DESCRIPTION

The following detailed description of various embodiments herein refers to the accompanying drawings, which show various embodiments by way of illustration. While these various embodiments are described in sufficient detail to enable those skilled in the art to practice the disclosure, it should be understood that other embodiments may be realized and that changes may be made without departing from the scope of the disclosure. Thus, the detailed description herein is presented for purposes of illustration only and not of limitation. Furthermore, any reference to singular includes plural embodiments, and any reference to more than one component or step may include a singular embodiment or step. Also, any reference to attached, fixed, connected, or the like may include permanent, removable, temporary, partial, full or any other possible attachment option. Additionally, any reference to without contact (or similar phrases) may also include reduced contact or minimal contact. It should also be understood that unless specifically stated otherwise, references to “a,” “an” or “the” may include one or more than one and that reference to an item in the singular may also include the item in the plural. Further, all ranges may include upper and lower values and all ranges and ratio limits disclosed herein may be combined.

Reference will now be made to the exemplary embodiments illustrated in the drawings, and specific language will be used herein to describe the same. It will nevertheless be understood that no limitation of the scope of the disclosure is thereby intended. Alterations and further modifications of the inventive features illustrated herein, and additional applications of the principles of the disclosure as illustrated herein, which would occur to one skilled in the relevant art and having possession of this disclosure, are to be considered within the scope of the disclosure.

In accordance with various example embodiments, temperature measurements and current measurements from the energy storage system (ESS) may be used to detect a short failure mode in a current measurement sensor. When this failure mode is detected, the battery management system (BMS) may be configured to open contactors to bring the battery, or battery stack to a safe state. In various embodiments, the ESS may be referred to as a stack switchgear (SSG), which may comprise the BMS and hardware components, such as contactors and switches, similar in design and function to the ESS described herein.

Disclosed herein are systems, devices and methods for fault detection. The fault detection systems, devices and methods may also be referred to herein a short-shunt detection system, devices and methods or current measurement circuit fault detection systems, devices and methods. The fault detection systems may be configured to detect if there is a failure in the current measurement circuit. The fault detection systems may be configured to detect if there is a failure in the current measurement circuit for both energy storage systems that are passively cooled or actively cooled. Further, disclosed are systems for determining if current measurements are incorrect, based on temperature gradients.

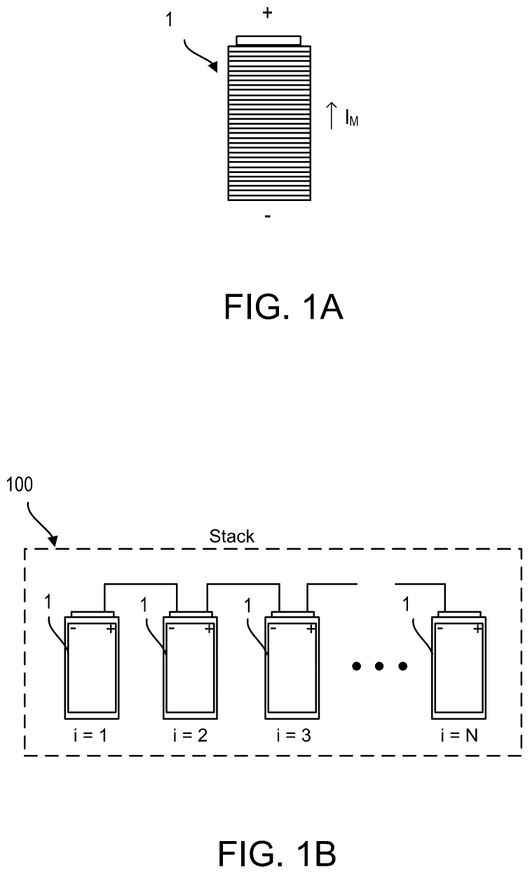

In the various example embodiments described herein, and with reference to FIGS. 1A and 1B, an ESS may comprise, in an example embodiment, a battery cell 1, or simply “cell” for short. In an example embodiment, the cell 1 comprises a single anode and cathode separated by electrolyte and is used to store and release electrical charge. Multiple anodes and cathodes may be joined together in parallel or series arrangements to produce cells that operate at higher voltage or current levels. The cell may be the smallest measurable unit of energy storage within an ESS. The current flowing through the cell 1 is denoted I_{M}, where a positive current flows out of the positive terminal. A typical cell can be physically arranged as a cylindrical cell, such as the 18650 and 21700 cylindrical lithium-ion format cells, button cells, prismatic cells, pouch cells, and/or the like. Moreover, a cell may comprise any chemistry and format suitable for rechargeable energy storage where multi-stack management is relevant. Generally, the cell 1 may be any rechargeable energy storage device with connection points for a single voltage measurement.

Moreover, an ESS may comprise, in an example embodiment, a battery module, or simply “module” for short. A module may comprise two or more cells connected in series or parallel arrangements or both series and parallel arrangements and grouped together. A module may be the smallest measurable unit in the ESS, if the individual cells are integrated into the module in such a way that measurement of voltage from the individual cells is not convenient.

Moreover, an ESS may comprise, in an example embodiment, a battery stack 100, stack of cells, or simply “stack” for short. The stack 100, in an example embodiment, comprises multiple cells or modules electrically connected in series. Thus, in an example embodiment, a stack 100 may comprise N cells, and each cell, in the stack of cells, may be noted as cell n wherein n=1 to N. It will be understood that N may be any positive integer number. For N>1, the stack comprises a number of cells, N. A group of series connected cells may be called a stack, or stack of cells or string.

It is noted that a group of stacks, connected in parallel, may comprise a battery bank (not shown). Thus, an ESS may comprise, in an example embodiment, a battery bank or simply “bank” for short. Moreover, a bank may comprise any suitable number of stacks.

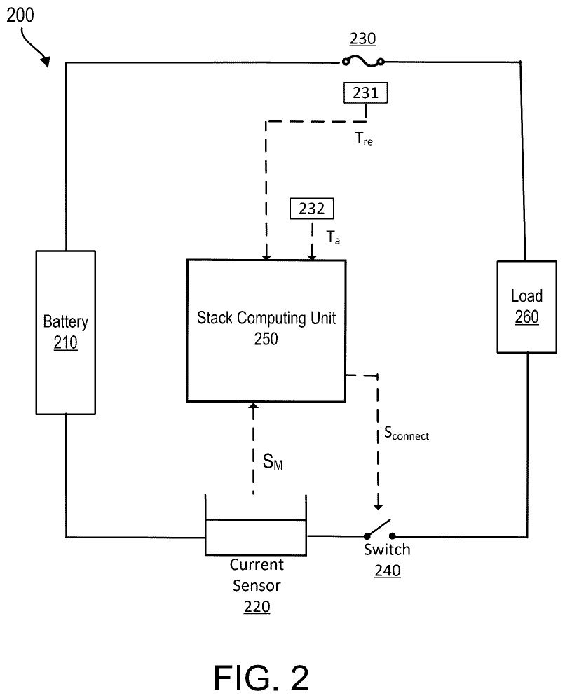

With reference now to FIG. 2, a fault detection system 200 for an energy storage system including the hardware components is shown in accordance with various embodiments. In various embodiments, the fault detection system 200 may comprise a battery 210 in connection with a current sensor 220. In various embodiments, the fault detection system 200 may further comprise a stack computing unit 250. In various embodiments, the battery 210 may include a battery cell, battery module, battery stack, battery pack or other suitable battery.

In various embodiments, the battery 210 may be positioned to provide current to a load 260. For example, the battery 210 may provide a DC current to the load 260. In various embodiments, the current sensor 220 may be a current shunt, a shunt sensor, a hall effect sensor or any suitable current sensor. In various embodiments, the current sensor 220 may be configured to measure a current flowing through the battery 210. In various embodiments, the current sensor 220 may be configured to measure a current provided to the load 260. In various embodiments, the current sensor 220 is positioned convenient to measuring the current into or out of the battery 210. In an example embodiment, the current sensor 220 may be configured to provide a signal measurement, S_{M}, to the stack computing unit 250. In various embodiments, stack computing unit 250 may determine the measured current based on the signal measurement, S_{M}. In one example embodiment, the signal measurement, S_{M}, is representative of the current sensed by current sensor 220. For example, the signal measurement, S_{M}, may be a voltage signal representative of the current sensed by current sensor 220. In various embodiment, the current sensor 220 may determine the current by providing a measured voltage to the stack computing unit 250, wherein the stack computing unit 250 may determine the measured current of the current sensor 220 based on the measured voltage and the resistance of the current sensor 220.

In various embodiments, the fault detection system 200 may further comprise a resistive element 230. In various embodiments, the resistive element 230 may comprise a fuse. In other example embodiments, the resistive element 230 may comprise a shunt. In yet another example embodiment, the resistive element 230 may comprised a connector, such as a connector to the battery or a connector to the load. Moreover, the resistive element 230 may comprise any component having a resistance that generates heat corresponding to a current flow through the resistive element 230. In various embodiments, the resistive element 230 may be an electrical safety device that is used to protect the energy storage system from overcurrent conditions. The resistive element 230 may be positioned within the same circuit as the battery 210 and current sensor 220 and may be positioned in proximity to the battery 210. In accordance with an example embodiment, the resistive element 230 may be electrically connected between the load 260 and the battery 210.

In various embodiments, the fault detection system 200 may comprise a switch 240. In various embodiments, the switch 240 maybe a contactor or other suitable connection device. Moreover, the switch 240 may be any suitable device for connecting or disconnecting the battery 210 from load 260. In various embodiments, the battery 210 and the load 260 may be connected by a shared DC bus, and the switch 240 may connect or disconnect the battery 210 from the load 260 by connecting or disconnecting the current of the shared DC bus.

In various embodiments, the fault detection system 200 may comprise a stack computing unit 250. The stack computing unit 250 may comprise hardware or software for performing the functions described herein. The stack computing unit 250 may receive current measurements from the current sensor 220. In various embodiments, the stack computing unit 250 may receive a signal from the current sensor 220 and the stack computing unit 250 may determine the measured current of the current sensor 220 based on the signal. For example, the stack computing unit 250 may receive a signal comprising a measured voltage by the current sensor 220 and the stack computing unit 250 may determine the measured current of the current sensor 220 based on the measured voltage and the resistance of the current sensor 220.

In various embodiments, the stack computing unit 250 may receive one or more temperature measurements from one or more temperature sensors. The temperature sensors can be any suitable type of temperature sensor, such as a resistive thermistor or a thermocouple followed by a suitable filter and an analog-to-digital converter. In various embodiments, the temperature measurements may comprise a resistive element temperature and/or an ambient temperature.

In various embodiments, the temperature sensor 231 may measure the resistive element temperature, Tᵣₑ. In various embodiments, where the resistive element 230 is a fuse, the resistive element temperature may also be referred to as a fuse temperature. The resistive element temperature may comprise a temperature measurement in proximity to the resistive element 230. In various embodiments, the temperature sensor 231 may be an integral component of the resistive element 230. In various embodiments, the temperature sensor 231 may be in close proximity to the resistive element 230 or attached to the resistive element 230 or integrated into the resistive element 230.

In various embodiments, the temperature sensor 232 may measure the ambient temperature. In various embodiments, the ambient temperature may be a temperature in proximity to the resistive element 230. In various embodiments, the temperature sensor 232 may be a temperature of the energy storage system that is not in close proximity to any of the components.

In an example embodiment, the temperature sensors 231, 232 may comprise or be in communication with one or more temperature measurement circuits for determining the resistive element temperature and/or the ambient temperature. The temperature measurements may be taken at any suitable interval, over time, and the temperature measurements are denoted herein by the subscript k, representing each time step.

In various embodiments, the stack computing unit 250 may determine and output signal, S_{connect}, based on one or more of the measured current, resistive element temperature, and ambient temperature. In various embodiments, the stack computing unit 250 may provide an output signal, S_{connect}, to the switch 240 to control the connection/disconnection of the battery 210 from the load 260. In various embodiments, the resistive element 230 may be configured to fuse open if the current through the fuse exceeds a threshold for a particular amount of time. However, the fuse may not be able to react fast enough to protect the load 260 in the event of a short. Moreover, in some instances the resistive element 230 is not a fuse and cannot fuse open to protect the load 260.

In various embodiments, the fault detection system 200 may determine whether there is a sudden rise in temperature, and/or little or no current flow across the current sensor 220. In various embodiments, the stack computing unit 250 may indicate a failure in the current measurement circuit based on the rise in temperature and/or low or no current flow across the shunt. The stack computing unit 250 may be configured to receive the measured current I_{M}, the resistive element temperature Tᵣₑ, and the ambient temperature Tₐ. The stack computing unit 250 may determine a failure in the current measurement circuit based on the measured current, the resistive element temperature, and the ambient temperature.

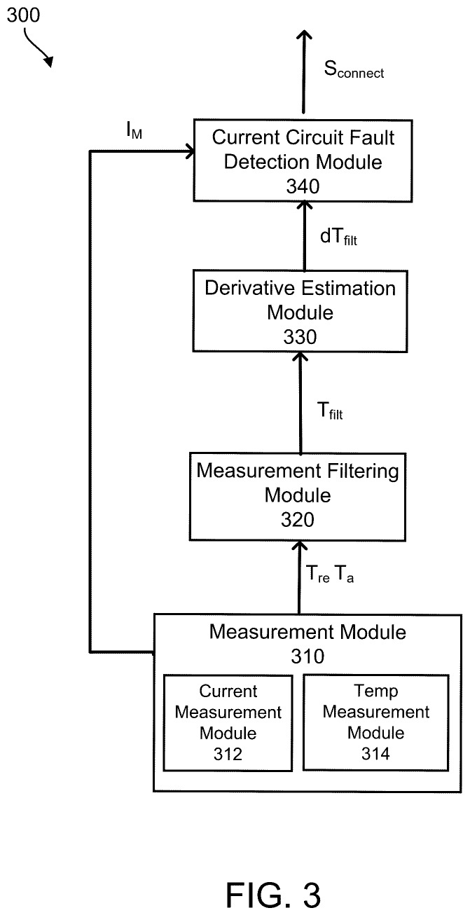

With reference now to FIG. 3, a fault detection system 300 is shown in accordance with various embodiments. The fault detection system 300 may comprise one or more modules for implementing fault detection system 200. In an example embodiment, the one or more modules are software modules. In various embodiments, the stack computing unit 250 may comprise one or more of the modules of fault detection system 300. In various embodiments, the fault detection system 300 may comprise a measurement module 310, a measurement filtering module 320, a derivative estimation module 330 and a current circuit fault detection module 340. In various embodiments, the measurement module 310, measurement filtering module 320, derivative estimation module 330 and current circuit fault detection module 340 may be implemented on the stack computing unit 250, as described with reference to FIG. 2.

In various embodiments, the measurement module 310 may comprise a current measurement module 312. The current measurement module 312 may measure the current, I_{M}, using the current sensor 220, as described with reference to FIG. 2. In various embodiments, the current measurement module 312 may comprise or be in communication with a current sensor positioned to measure the current into or out of a stack in an ESS or other battery or battery stack. In various embodiments, the cells in each of the one or more stacks may be connected in series, as described in reference to FIG. 1, therefore the measurement of the current into or out of the stack is equivalent to the current into or out of each cell. In an example embodiment, a stack may have only one cell. In various embodiments, the current measurement module 312 is configured to sample current at a time step k. For example, the current measurement module 312 may sample the current of each of the one or more stacks in 1 second intervals, though any sampling period can be used. In an example embodiment, the current measurement module 312 can be any suitable current measurement device that is configured to determine a current (into or out of the stack) and to generate a measured current, I_{M}. In various embodiments, the current circuit fault detection module 340 may be configured to receive the measured current, I_{M}, from the measurement module 310.

In an example embodiment, the measurement module 310 may further comprise a temperature measurement module 314. The temperature measurement module 314 may determine the temperature measurements using the temperature sensors 231, 232 as described with reference to FIG. 2. In an example embodiment, the temperature measurement module 314 may comprise one or more temperature sensors.

In various embodiments, the temperature measurement module 314 may receive one or more resistive element temperatures from the resistive element temperature sensor 231. The temperature measurement module 314 may determine the resistive element temperature Tᵣₑ at any suitable interval, over time, and the temperature measurements are denoted herein by the subscript k, representing each time step.

In various embodiments, the temperature measurement module 314 may receive one or more ambient temperatures from the temperature sensor 232.

The ambient temperature sensor 232 may be any suitable device for measuring the temperature in the vicinity of the fault detection system 200. The ambient temperature, Tₐ, may include an average or singular measured temperature of the environment used for normalizing the amount of temperature rise of the resistive element 230. The ambient temperature sensor 232 could be near, but off board the fault detection system 300, in another example embodiment.

In an example embodiment, the measurement module 310, may further comprise one or more temperature measurement circuits for measuring the resistive element temperature and/or the ambient temperature. In an example embodiment, the temperature measurement circuit may comprise the temperature sensors 231, 232.

### Detection Approach:

In various embodiments, the measurement filtering module 320, may be configured to receive the resistive element temperature Tᵣₑ and the ambient temperature Tₐ from the measurement module 310. In various embodiments, the measurement filtering module 320 may calculate a differenced resistive element temperature, T_{diff}, also referred to as differenced temperature. The differenced temperature may be the difference between the resistive element temperature, Tᵣₑ, and the ambient temperature Tₐ, which may be calculated with the equation:

$${T}_{diff} = {T}_{re} - {T}_{a} .$$

Subtracting the ambient temperature from the resistive element temperature provides a temperature measurement of the resistive element 230 that is not dependent on the ambient condition.

In various embodiments, the differenced temperature T_{diff} is further filtered to remove measurement noise to determine the filtered resistive element temperature or filtered differenced resistance element temperature, T_{filt}. In various embodiments, the filtering method can be a first order low pass IIR filter or an exponentially weighted moving average filter. In various embodiments, the filtering method will take the previous filtered T_{filt,k-1} and estimate a new filtered estimate T_{filt,k} using the newest T_{diff,k} value. The equation is shown below:

$${T}_{filt , k} = ( 1 - {λ}_{c} ) {T}_{filt , k - 1} + {λ}_{c} {T}_{diff , k}$$

where λ_{c} is the constant smoothing factor used in filtering the temperature measurements. In various embodiments, any filter that can remove high frequency noise can be used. The measurement filtering module is configured to provide the filtered temperature measurement of the resistive element to the derivative estimation module 330.

In various embodiments, the derivative estimation module 330 may calculate the average rate of change of the filtered resistive element temperature, T_{filt}, over a fairly large time step. The time step may be a configurable threshold and denoted as L. The average rate of change of the filtered resistive element temperature may be calculated using a forward difference as shown below:

$${dT}_{filt} = \frac{{T}_{filt , k + L} - {T}_{filt , k}}{{t}_{k + L} - {t}_{k}}$$

Where T_{filt,k+L} is the filtered resistive element temperature at time t_{k+L} and T_{filt,k} is the filtered resistive element temperature at time tₖ. In various embodiments, the dT_{filt} may be referred to as the average rate of change of the filtered differenced resistive element temperature.

In various embodiments, the filtered resistive element temperature may be calculated using a central difference, a fourth-order central difference or any suitable method for calculating derivatives. The derivative estimation module 330 is configured to provide the derivative dT_{filt} to the current circuit fault detection module 340.

The current circuit fault detection module 340 may be configured to receive the derivative estimates dT_{filt} and the measured current I_{M}, and to evaluate whether there is a failure in the current measurement circuit. The current circuit fault detection module 340 may be configured to evaluate whether there is a failure in the current measurement circuit based on the derivative estimates dT_{filt} and the measured current I_{M}. The current circuit fault detection module 340 may determine if a short-shunt condition might exist based on one or more of the scenarios described herein. In various embodiments, the current circuit fault detection module 340 may evaluate whether there is a failure in the current measurement circuit, including for example, a short across current sensor 220, a failure in stack computing unit 250, or other locations between the battery 210 and load 260.

### Scenario #1

In various embodiments, the fault detection system 300 may detect a fault within the current measurement circuit, if the following two conditions are met:
Condition 1: There is heat generation from the fuse or resistive element.
Condition 2: The current measurements indicate that there is no current flowing.

In various embodiments, to determine if there is heat generation from the fuse or resistive element (condition 1), the fault detection system 300 may be configured to check if the average rate of change of the filtered resistive element temperature is greater than a configurable threshold dT_{thresh_1}. In various embodiments, if the absolute value of the measured current I_{M} is less than a current threshold, Iₜₕᵣₑₛₕ, this means condition 2 is satisfied.

Therefore, if the above two conditions are satisfied, a failure in the current measurement circuit is detected. Written as an equation:

dT_{filt} is greater than dT_{thresh_1} AND absolute value of I_{M} is less than Iₜₕᵣₑₛₕ;

Where dT_{thresh_1} is the minimum threshold value of the temperature derivative for scenario #1, and Iₜₕᵣₑₛₕ represent the maximum current threshold value below which the current is said to be zero or not flowing.

### Scenario #2

In various embodiments, a fault may be detected within the current measurement circuit even when the rate of change of the resistive element temperature with respect to time is zero, if the following three conditions are met. This will be referred to as scenario #2.
Condition 1: A large temperature difference is present between the fuse/resistive element and the ambient temperature.
Condition 2: The current measurements indicate that there is no current flowing.
Condition 3: The system is not cooling.

In various embodiments, to determine if there is a large temperature difference between the resistive element and ambient temperature (condition 1), the fault detection system 300 may be configured to check if T_{filt} is greater Tₜₕᵣₑₛₕ. In various embodiments, to check if condition 2 is met, the fault detection system 300 may be configured to determine whether the absolute value of the measured current I_{M} is less than a current threshold, Iₜₕᵣₑₛₕ. In various embodiments, to determine if the system is not cooling (condition 3), the fault detection system 300 may be configured to check if the average rate of change of the filtered resistive element temperature dT_{filt} is greater than zero or a very small configurable threshold dT_{thresh_2}.

Written as an equation:

dT_{filt} is greater than dT_{thresh_2} AND absolute value of I_{M} is less than Iₜₕᵣₑₛₕ AND T_{filt} is greater Tₜₕᵣₑₛₕ.

Where the temperature threshold, Tₜₕᵣₑₛₕ, may represent the minimum threshold value for the filtered temperature measurements, dT_{thresh_2}, the minimum threshold value of the temperature derivative for scenario #2 and Iₜₕᵣₑₛₕ represent the maximum current threshold value below which the current is said to be zero.

In various embodiments, when the two conditions for the first scenario are met, the current circuit fault detection module 340 generates an output “True” signal, which is a fault signal. In various embodiments, when the three conditions for the second scenario are met, the current circuit fault detection module 340 generates an output “True” signal, which is a fault signal. In various embodiments, the current circuit fault detection module 340 may be the software that is implemented on the hardware which is the stack computing unit 250. In various embodiments, the current circuit fault detection module 340 may generate a fault signal F_{signal}. In various embodiments, the fault signal may comprise a Boolean (either “True” or “False”). In various embodiments, where the fault signal is “True” for a duration of time, denoted t_{hys}, then the connection signal, denoted S_{connect} will be set to “True”. In various embodiments, when the connection signal S_{connect} is set to “True”, the stack computing unit 250 or other controller may send a signal to open the contactors, such as switch 240. For example, the switch 240 may receive the connection signal from the stack computing unit 250 in the form of a voltage/electrical signal, Boolean value or other signal and be configured to open the switch 240 when the connection signal is received. In various embodiments, the fault detection system 300 and/or fault detection system 200 may comprise a controller or software module configured to receive the connection signal and send a control signal to the switch 240 to control the contactors of the switch. Opening the contactors will protect the load. In a fault condition, where the current measurement circuit has failed, opening the contactors will bring the battery to a safe state. Thus, the fault detection system 300 is configured to detect a fault based on temperature measurements and current measurement, and to automatically open the contactors to protect the battery or load. In various embodiments, when the ESS is composed of multiple stacks, the fault detection system 300 is configured to detect a fault based on temperature measurements and current measurement for each stack and automatically open the contactors for that stack to protect the battery or load.

In various embodiments, when the connection signal S_{connect} is set to “True”, the user will be notified of a fault in the system. In various embodiments, when the connection signal S_{connect} is set to “True”, the connection signal will be sent to an Energy Management System (EMS) or other system for storing historical records of the connection signal.

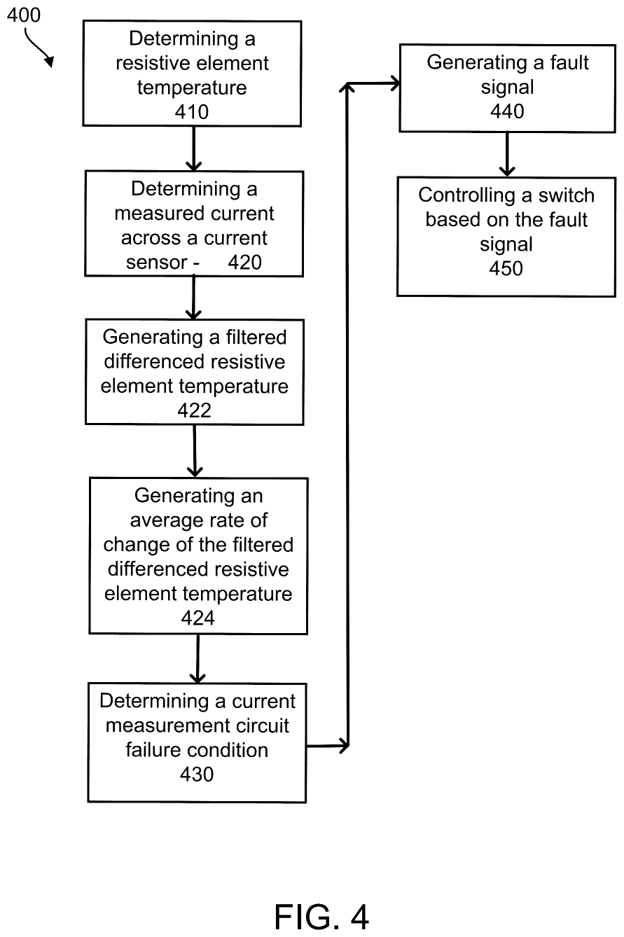

With reference now to FIG. 4, an example method 400 for detecting a current measurement circuit failure in an energy storage system is disclosed. The energy storage system may comprise a load and a battery. In an example embodiment, the method may comprise determining a resistive element temperature of a resistive element (410). For example, determining the resistive element temperature may be based on a measurement by a temperature sensor. In this example embodiment, the resistive element is electrically connected between the load and the battery. This determination may be made by a computing unit, e.g., temperature measurement module 314.

In an example embodiment, the method 400 may further comprise determining a measured current across a current sensor connected to the energy storage system (420). This determination may be made by a computing unit, e.g., current measurement module 312. In an example embodiment, the method may further comprise generating a filtered differenced resistive element temperature (422). The filtered differenced resistive element temperature may be generated, for example, by a measurement filtering module 320. Thus, in an example embodiment, the method may comprise filtering the differenced resistive element temperature to generate a filtered differenced resistive element temperature T_{filt}. In an example embodiment, the differenced resistive element temperature is based on a difference between the resistive element temperature and an ambient temperature. In an example embodiment, the method may further comprise generating an average rate of change of the filtered differenced resistive element temperature, dT_{filt} (424), and this derivative filtered differenced resistive element temperature may be generated, for example, by a derivative estimation module 330 based on the filtered differenced resistive element temperature.

In an example embodiment, the method may further comprise determining a current measurement circuit failure condition based on the resistive element temperature and the measured current (430). The determination of the failure condition may be made by a computing unit, e.g., current circuit fault detection module 340. In accordance with various example embodiments, the determining the current measurement circuit failure condition, may further be based on a filtered differenced resistive element temperature and the measured current. In other example embodiments, determining the current measurement circuit failure condition may further comprise determining that both: (a) the resistive element is generating heat; and (b) the measured current is below a current threshold. In yet other example embodiments, determining the current measurement circuit failure condition may further comprise determining that both: (a) the average rate of change of the differenced resistive element temperature is greater than a temperature derivative threshold; and (b) the measured current is less than a current threshold. Moreover, in an example embodiment, determining a failure in the current sensor is met further comprises determining that: (a) the filtered differenced resistive element temperature is greater than a threshold temperature; (b) the measured current is below a current threshold; and (c) the average rate of change of the filtered differenced resistive element temperature is greater than a temperature derivative threshold.

In an example embodiment, the method may further comprise generating a fault signal based on the determining the current measurement circuit failure condition (440). The fault signal may be generated, for example, by current circuit fault detection module 340 or other computing unit. In an example embodiment, the current circuit fault detection module 340 may generate a connection signal, the connection signal based on the fault signal, which is asserted over a period of time.

In an example embodiment, the method may further comprise controlling a switch based on the fault signal or based on the connection signal (450). The switch may be controlled by a computing unit, the current circuit fault detection module 340, or any suitable controller. In an example embodiment, when a fault is present, the method is configured to open a switch positioned between the battery and the load, thus bringing the battery and load to a safe state.

In various embodiments, the modules discussed herein can be implemented as and may include one or more processors and/or one or more tangible, non-transitory memories (e.g., memory) and be capable of implementing logic. Each processor can be a general-purpose processor, a digital signal processor (“DSP”), an application specific integrated circuit (“ASIC”), a field programmable gate array (“FPGA”), or other programmable logic device, discrete gate or transistor logic, discrete hardware components, or any combination thereof. The controller can comprise a processor configured to implement various logical operations in response to execution of instructions, for example, instructions stored on a non-transitory, tangible, computer-readable medium configured to communicate with the modules discussed.

System program instructions and/or controller instructions can be loaded onto a non-transitory, tangible computer-readable medium of the modules having instructions stored thereon that, in response to execution by a processor of the modules, cause the modules to perform various operations. The term “non-transitory” is to be understood to remove only propagating transitory signals per se from the claim scope and does not relinquish rights to all standard computer-readable media that are not only propagating transitory signals per se. Stated another way, the meaning of the term “non-transitory computer-readable medium” and “non-transitory computer-readable storage medium” should be construed to exclude only those types of transitory computer-readable media which were found in In Re Nuijten to fall outside the scope of patentable subject matter under 35 U.S.C. § 101.

Benefits, other advantages, and solutions to problems have been described herein regarding specific embodiments. Furthermore, the connecting lines shown in the various figures contained herein are intended to represent exemplary functional relationships and/or physical couplings between the various elements. It should be noted that many alternative or additional functional relationships or physical connections may be present in a practical system. However, the benefits, advantages, solutions to problems, and any elements that may cause any benefit, advantage, or solution to occur or become more pronounced are not to be construed as critical, required, or essential features or elements of the disclosure. The scope of the disclosure is accordingly limited by nothing other than the appended claims, in which reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B, and C may be present in a single embodiment; for example, A and B, A and C, B and C, or A and B and C. Different cross-hatching is used throughout the figures to denote different parts but not necessarily to denote the same or different materials.

Systems, methods, and apparatus are provided herein. In the detailed description herein, references to “one embodiment,” “an embodiment,” “various embodiments,” etc. indicate that the embodiment described may include a particular feature, structure, or characteristic, but every embodiment may not necessarily include the feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether explicitly described. After reading the description, it will be apparent to one skilled in the relevant art(s) how to implement the disclosure in alternative embodiments.

Furthermore, no element, component, or method step in the present disclosure is intended to be dedicated to the public regardless of whether the element, component, or method step is explicitly recited in the claims. No claim element herein is to be construed under the provisions of 35 U.S.C. 112(f) unless the element is expressly recited using the phrase “means for.” As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

It should be understood, however, that the detailed description and specific examples, while indicating exemplary embodiments of the present disclosure, are given for purposes of illustration only and not of limitation. Many changes and modifications within the scope of the instant disclosure may be made without departing from the spirit thereof, and the disclosure includes all such modifications. The corresponding structures, materials, acts, and equivalents of all elements in the claims below are intended to include any structure, material, or acts for performing the functions in combination with other claimed elements as specifically claimed. The scope of the disclosure should be determined by the appended claims and their legal equivalents, rather than by the examples given above. For example, the operations recited in any method claims may be executed in any order and are not limited to the order presented in the claims. Moreover, no element is essential to the practice of the disclosure unless specifically described herein as “critical” or “essential.”

What is claimed:

1. A method for detecting a current measurement circuit failure in an energy storage system comprising a load and a battery, the method comprising:
determining a resistive element temperature of a resistive element, wherein the determining the resistive element temperature is based on a measurement by a temperature sensor, wherein the resistive element is electrically connected between the load and the battery;
determining, by a computing unit, a measured current across a current sensor connected to the energy storage system;
determining, by the computing unit, a current measurement circuit failure condition based on the resistive element temperature and the measured current;
generating, by the computing unit, a fault signal, the fault signal based on the determining the current measurement circuit failure condition; and
controlling, by the computing unit, a switch based on a connection signal, wherein the connection signal is based on the fault signal, the switch positioned between the battery and the load.

2. The method of claim 1, further comprising:
determining, by the computing unit, an average rate of change of a differenced resistive element temperature, wherein the differenced resistive element temperature is based on a difference between the resistive element temperature and an ambient temperature.

3. The method of claim 2, further comprising:
filtering, by the computing unit, the differenced resistive element temperature to generate a filtered differenced resistive element temperature; and
determining, by the computing unit, an average rate of change of the filtered differenced resistive element temperature.

4. The method of claim 3, wherein the determining the current measurement circuit failure condition, by a current circuit fault detection module, is based on the filtered differenced resistive element temperature and the measured current.

5. The method of claim 2, wherein the determining the current measurement circuit failure condition further comprises determining that both:
(a) the resistive element is generating heat; and
(b) the measured current is below a current threshold.

6. The method of claim 4, wherein the determining the current measurement circuit failure condition further comprises determining that:
(a) the average rate of change of the differenced resistive element temperature is greater than a temperature derivative threshold; and
(b) the measured current is less than a current threshold.

7. The method of claim 3, wherein the determining the current measurement circuit failure condition further comprises determining that:
(a) the filtered differenced resistive element temperature is greater than a threshold temperature;
(b) the measured current is below a current threshold; and
(c) the average rate of change of the filtered differenced resistive element temperature is greater than a temperature derivative threshold.

8. The method of claim 1, further comprising:
determining, by the computing unit, the connection signal, the connection signal based on the fault signal, which is asserted over a period of time.

9. The method of claim 1, wherein the fault signal is a voltage signal and the fault signal is used to open the switch and bring the battery to a safe state.

10. The method of claim 1, wherein the resistive element is a fuse.

11. A fault detection device for an energy storage system comprising a battery and a load, the device comprising:
a temperature measurement module configured to determine a resistive element temperature and an ambient temperature, wherein the resistive element temperature is based on a resistive element electrically connected between the load and the battery;
a current measurement module configured to determine a measured current of a current sensor connected to the energy storage system;
a current circuit fault detection module configured to determine a failure condition is met based on the resistive element temperature, the ambient temperature and the measured current and generate a fault signal based on the failure condition; and
a switch positioned between the load and the battery, the switch controlled based on a connection signal, the connection signal based on the fault signal received from the current circuit fault detection module.

12. The device of claim 11, further comprising a measurement filtering module configured to receive the resistive element temperature and the ambient temperature from the temperature measurement module and determine a filtered resistive element temperature based on the resistive element temperature and the ambient temperature.

13. The device of claim 12, further comprising a derivative estimation module configured to receive the filtered resistive element temperature from the measurement filtering module and determine an average rate of change of the filtered resistive element temperature based on the filtered resistive element temperature.

14. The device of claim 13, wherein the current circuit fault detection module is configured to receive the average rate of change of the filtered resistive element temperature from the derivative estimation module and determine the failure condition is met based on the average rate of change of the filtered resistive element temperature.

15. A fault detection system for an energy storage system comprising a battery and a load, the system comprising:
a current sensor in connection between the battery and the load, the current sensor having a measured current;
a first temperature sensor for measuring a resistive element temperature, the resistive element temperature based on the temperature of a resistive element, wherein the resistive element is electrically connected between the battery and the load;
a second temperature sensor for measuring an ambient temperature, the ambient temperature based on the temperature of the energy storage system;
a computing unit in communication with the current sensor, the first temperature sensor and the second temperature sensor, the computing unit comprising a tangible, non-transitory memory configured to communicate with the processor, the tangible, non-transitory memory having instructions stored thereon that, in response to execution by the processor, cause the processor to perform operations comprising:
determining a failure condition is met based on the resistive element temperature, the ambient temperature and the measured current;
generating a fault signal, the fault signal based on the failure condition; and
controlling a switch based on a connection signal, the connection signal based on the fault signal, the switch in communication with the switch and the battery.

16. The device of claim 15, further comprising a measurement filtering module configured to receive the resistive element temperature and the ambient temperature from a temperature measurement module and determine a filtered resistive element temperature based on the resistive element temperature and the ambient temperature.

17. The device of claim 16, further comprising a derivative estimation module configured to receive the filtered resistive element temperature from the measurement filtering module and determine an average rate of change of the filtered resistive element temperature based on the filtered resistive element temperature.

18. The device of claim 17, wherein a current circuit fault detection module is configured to:
receive the average rate of change of the filtered resistive element temperature from the derivative estimation module; and
determine the failure condition is met based on the average rate of change of the filtered resistive element temperature.

19. The device of claim 18, wherein the determining the failure condition is met further comprises determining that:
(a) an average rate of change of a differenced resistive element temperature is greater than a temperature derivative threshold; and
(b) the measured current is less than a current threshold.

20. The device of claim 18, wherein the determining the failure condition is met further comprises determining that:
(a) a filtered differenced resistive element temperature is greater than a threshold temperature;
(b) the measured current is below a current threshold; and
(c) an average rate of change of the filtered differenced resistive element temperature is greater than a temperature derivative threshold.
